(19) United States
(12) Patent Application Publication
(10) Pub. No.: US 2026/0241497 A1
(43) Pub. Date: Aug. 20, 2026

(54) PULSATING HEAT PIPE MODULE COMPRISING SEPARABLE FLOW PATH PLATES AND MANUFACTURING METHOD THEREOF

(71) Applicant: JNC Materials Co., Ltd., Jecheon-si, Chungcheongbuk-do (KR)

(72) Inventors: Jun Sun CHA, Anyang-si, Gyeonggi-do (KR); CHANG KUN LEE, Seoul (KR); Joo Sang KIM, Daejeon (KR)

(73) Assignee: JNC Materials Co., Ltd., Jecheon-si, Chungcheongbuk-do (KR)

(21) Appl. No.: 19/160,456

(22) PCT Filed: Nov. 30, 2023
(86) PCT No.: PCT/KR2023/019566

§ 371 Date: Aug. 27, 2025

(30) Foreign Application Priority Data
Mar. 17, 2023 (KR) 10-2023-0034940

(51) Int. Cl. B23P 15/26; F28D 15/02; F28F 3/08

(52) U.S. Cl. CPC B23P 15/26; F28D 15/0233; F28F 3/08; F28F 2255/08

(57) ABSTRACT

A pulsating heat pipe module comprising separable flow path plates and a manufacturing method thereof, according to the present invention, press-form a single base plate into two plates, first and second flow path plates, the channel therebetween becoming a working fluid channel, and therefore, work time and manufacturing costs are reduced due to the ease of production, thus enabling mass production. In addition, the two plates, the first and second flow path plates, are coupled, by an assembly guide unit, to an upper plate and a lower plate to be assembled at accurate positions and form a working fluid channel, thereby simplifying work. Moreover, the working fluid channel formed by the two plates, the first and second flow path plates, has no stepped portions along the flowing path of a working fluid, thus minimizing the flow resistance thereof.

### TECHNICAL FIELD

The present invention relates to a pulsating heat pipe module comprising separable flow path plates and a manufacturing method thereof, and more particularly, to a pulsating heat pipe module in which separable flow path plates having a working fluid channel of the pulsating heat pipe module formed therein, are formed using a press method so that work time and manufacturing costs are reduced and thus productivity can be enhanced.

### BACKGROUND ART

Recently, concern about heat dissipation has been increasing due to advancement in high performance and miniaturization of electronic devices.

In the related art, a bar type heat pipe that dissipates heat using a phase change of a working fluid has been mainly used, and this method is a method whereby the working fluid is circulated and cooled using a capillary pumping force of a wick provided inside the heat pipe.

However, heat pipes according to the related art cannot be driven in a top heating method or the like due to a low capillary force compared to gravity.

Thus, recently, concern about a pulsating heat pipe which has no wick structure and cools a high-temperature portion by self-pulsating while a working fluid having a liquid slug shape in which liquid and gas phases alternate, forms a slug-train and circulates a closed-loop flow path, has been increasing.

However, it is difficult to manufacture pulsating heat pipes compared to heat pipes according to the related art, because internal flow paths of the pulsating heat pipes are complicated, and much time and many costs are required to manufacture flow paths using photolithography methods.

### DETAILED DESCRIPTION OF THE INVENTION

### Technical problem

The present invention provides a pulsating heat pipe module in which work time and manufacturing costs are reduced so that productivity can be enhanced, and a manufacturing method thereof.

### Technical Solution

According to an aspect of the present invention, there is provided a method of manufacturing a pulsating heat pipe module comprising separable flow path plates, the method including: a first press-forming operation in which a first flow path plate is formed by piercing processing a first hole in a preset first pattern on a first base plate; a second press-forming operation in which a second flow path plate is formed by piercing processing a second hole in a preset second pattern on a scrab plate that is separated from the first base plate when the first flow path plate is formed and recovered; and a coupling operation in which the second flow path plate is arranged inside the first hole of the first flow path plate so that a flow path between the first flow path plate and the second flow path plate constitutes a working fluid channel of a pulsating heat pipe module and an upper plate and a lower plate are stacked on upper and lower surfaces of the first and second flow path plates and coupled to each other, thereby completing the pulsating heat pipe module.

The method may further include a third press-forming operation in which an assembly guide portion guiding a mutual coupling position on the first flow path plate, the second flow path plate, the upper plate, and the lower plate.

The assembly guide portion may include a first protrusion that is press-formed to protrude from at least one of the upper plate and the lower plate toward the other one, a first coupling hole formed in the first flow path plate and piercing processed so that the first protrusion passes through the first coupling hole, and a second coupling hole formed in the other one of the upper plate and the lower plate and piercing processed so that the first protrusion passing through the first coupling hole is coupled to the second coupling hole.

The assembly guide portion may include a second protrusion that is press-formed to protrude from at least one of the upper plate and the lower plate toward the other one, a third coupling hole formed in the second flow path plate and piercing processed so that the second protrusion passes through the third coupling hole, and a fourth coupling hole formed in the other one of the upper plate and the lower plate and piercing processed so that the second protrusion passing through the third coupling hole is coupled to the fourth coupling hole.

A plurality of first flow path guides may be formed in a shape of a rod that is elongated in one direction from a remaining part after the first hole is piercing processed in the first flow path plate.

A plurality of second flow path guides may be formed in a shape of a rod that is elongated in one direction from a remaining part after the second hole is piercing processed in the second flow path plate.

In the coupling operation, the first flow path guides and the second flow path guides may be alternately arranged to be spaced apart from one another by a preset distance.

The first press-forming operation may further include shape-processing a border of the first base plate in an outline shape of the pulsating heat pipe module.

The upper plate and the lower plate may be formed by shape-processing a second base plate in an outline shape of the pulsating heat pipe module.

The working fluid channel may have at least a part that is a flow path in a zigzag form, and the working fluid channel may include a working fluid injection hole formed in the first flow path plate to inject a working fluid, first flow path holes that are connected to the working fluid injection hole, are formed long in one direction and are spaced apart from each other by a set distance to guide the working fluid in the one direction, and second flow path holes that are arranged alternately with the first flow path holes between the first flow path holes, are formed long in the one direction, and guide the working fluid passing through the first flow path holes in an opposite direction to the one direction.

The first flow path holes and the second flow path holes may have different cross-sectional areas.

According to another aspect of the present invention, there is provided a method of manufacturing a pulsating heat pipe module comprising separable flow path plates, the method including: forming a cover plate used as an upper plate and a lower plate, by shape-processing two base plates among a plurality of base plates in a preset outline shape of a pulsating heat pipe module; forming a first flow path plate in which the other base plate among the plurality of base plates is shape-processed in the outline shape and a first hole is piercing processed in a preset first pattern so that a plurality of rod-shaped first flow path guides are formed in a remaining part after piercing processing the first hole; forming a second flow path plate in which a second hole is piercing processed in a preset second pattern to cross the first hole on a scrab plate that is separated from the base plate when the first flow path plate is formed and recovered, so that a plurality of rod-shaped second flow path guides are formed in a remaining part after piercing processing the second hole; processing an assembly guide portion guiding a mutual coupling position on the first flow path plate, the second flow path plate, the upper plate, and the lower plate; and arranging the second flow path plate inside the first hole of the first flow path plate, wherein the first flow path guides and the second flow path guides are alternately arranged so that a flow path between the first flow path guide and the second flow path guide constitutes a working fluid channel of the pulsating heat pipe module and stacking the upper plate and the lower plate on upper and lower surfaces of the first and second flow path plates and coupling the upper plate and the lower plate to each other to complete the pulsating heat pipe module.

According to another aspect of the present invention, there is provided a pulsating heat pipe module comprising separable flow path plates, including: a first flow path plate formed by shape-processing a base plate in an outline shape of a pulsating heat pipe module and by piercing processing a first hole in a preset first pattern; a second flow path plate, which is formed by piercing processing a second hole in a preset second pattern on a scrab plate that is separated from the base plate when the first flow path plate is formed and recovered and is arranged inside the first hole so that a flow path between the second flow path plate and the first flow path plate constitutes a working fluid channel of the pulsating heat pipe module; an upper plate stacked on an upper surface of the first and second flow path plates and then coupled and shielding an upper surface of the working fluid channel; and a lower plate stacked on a lower surface of the first and second flow path plates and then coupled and shielding a lower surface of the working fluid channel.

The pulsating heat pipe module may further include an assembly guide portion that is press-formed on at least one of the first flow path plate, the second flow path plate, the upper plate, and the lower plate and guides an assembly position with the other plate.

The assembly guide portion may include a first protrusion that is press-formed to protrude from at least one of the upper plate and the lower plate toward the other one, a first coupling hole formed in the first flow path plate and piercing processed so that the first protrusion passes through the first coupling hole, a second coupling hole formed in the other one of the upper plate and the lower plate and piercing processed so that the first protrusion passing through the first coupling hole is coupled to the second coupling hole, a second protrusion that is press-formed to protrude from at least one of the upper plate and the lower plate toward the other one, a third coupling hole formed in the second flow path plate and piercing processed so that the second protrusion passes through the third coupling hole, and a fourth coupling hole formed in the other one of the upper plate and the lower plate and piercing processed so that the second protrusion passing through the third coupling hole is coupled to the fourth coupling hole.

### Effects of the Invention

A pulsating heat pipe module comprising separable flow path plates and a manufacturing method thereof according to the present invention, press-form a single base plate into two plates, first and second flow path plates, the channel therebetween becoming a working fluid channel. Therefore, work time and manufacturing costs are reduced due to the ease of production, thus enabling mass production.

In addition, the two plates, the first and second flow path plates, are coupled, by an assembly guide unit, to an upper plate and a lower plate to be assembled at accurate positions and form a working fluid channel, thereby simplifying work.

Moreover, the working fluid channel formed by the two plates, the first and second flow path plates, has no stepped portions along the flowing path of a working fluid, thus minimizing the flow resistance thereof.

In addition, since a total of four plates, including the upper plate, lower plate, and the first and second flow path plates, are press-formed and then stacked and coupled, the structure is simple and manufacturing is very easy.

Furthermore, by forming two first and second flow path plates through two piercing processes on a single plate, the waste from the base plate is minimized, greatly increasing the utilization of raw materials, thereby reducing material costs.

### DESCRIPTION OF THE DRAWINGS

FIG. 1 is a perspective view illustrating a pulsating heat pipe module according to a first embodiment of the present invention.

FIG. 2 is an exploded perspective view of the pulsating heat pipe module shown in FIG. 1 from the front.

FIG. 3 is an exploded perspective view of the pulsating heat pipe module shown in FIG. 1 from the rear.

FIG. 4 shows an example in which a first flow path plate and a second flow path plate are piercing processed on a base plate according to the first embodiment of the present invention.

FIG. 5 shows an example in which the base plate according to the first embodiment of the present invention is piercing processed so that the first flow path plate and a scrab plate are formed.

FIG. 6 shows an example in which the scrab plate according to the first embodiment of the present invention is piercing processed so that the second flow path plate is formed.

FIG. 7 shows a state in which the second flow path plate is arranged on a first hole of the first flow path plate according to the first embodiment of the present invention.

FIG. 8 is a cross-sectional view of a first protrusion formed on a lower plate according to the first embodiment of the present invention.

FIG. 9 is a flowchart illustrating a method of manufacturing a pulsating heat pipe module comprising separable flow path plates according to the first embodiment of the present invention.

FIG. 10 is a view illustrating flow path holes of separable flow path plates according to a second embodiment of the present invention.

### MODE OF THE INVENTION

Hereinafter, embodiments of the present invention will be described below with reference to the accompanying drawings.

A pulsating heat pipe module according to an embodiment of the present invention cools high-temperature portions by self vibrating as a working fluid in the form of a liquid slug forms a slug-train and circulates through a close-loop flow path.

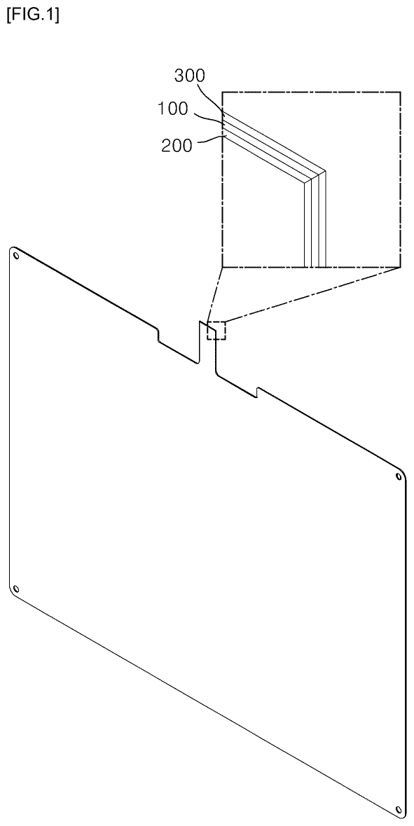

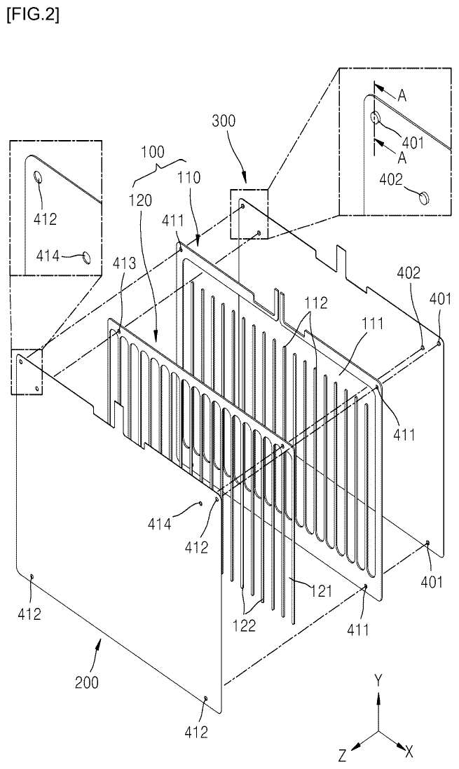

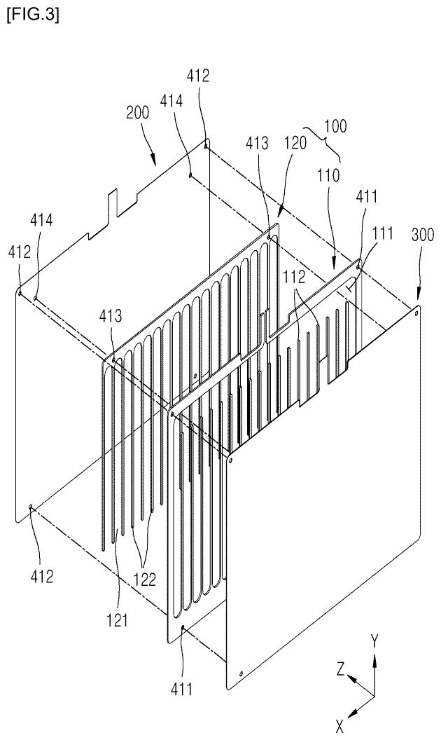

FIG. 1 is a perspective view illustrating a pulsating heat pipe module according to a first embodiment of the present invention. FIG. 2 is an exploded perspective view of the pulsating heat pipe module shown in FIG. 1 from the front. FIG. 3 is an exploded perspective view of the pulsating heat pipe module shown in FIG. 1 from the rear.

Referring to FIGS. 1 and 3, the pulsating heat pipe module according to the first embodiment of the present invention includes separable flow path plates 100 including first and second flow path plates 110 and 120, an upper plate 200, and a lower plate 300, and is formed by stacking a total of four plates.

The separable flow path plates 100, the upper plate 200, and the lower plate 300 are made of a metal material and have a plate shape with a predetermined set thickness. Here, it will be described that the metal material is aluminum, copper or the like, but embodiments are not limited thereto, and other metal materials are usable. It will be described that the set thickness is about 0.5 mm to 3.0 mm.

It will be described that the separable flow path plates 100, the upper plate 200 and the lower plate 300 are made of the same material and have the same thickness, but embodiments are not limited thereto, and the separable flow path plates 100, the upper plate 200 and the lower plate 300 may also be made of different materials and have different thicknesses.

In the present embodiment, it will be described that the separable flow path plates 100, the upper plate 200 and the lower plate 300 are processed using the same base plate B. However, embodiments are not limited thereto, and the separable flow path plates 100 may also use a first base plate that is preset, and the upper plate 200 and the lower plate 300 may also use a second base plate made of a different material or having a different thickness from the first base plate.

The separable flow path plates 100, the upper plate 200, and the lower plate 300 are all formed. The forming method of the separable flow path plates 100, the upper plate 200, and the lower plate 300 will be described in detail later.

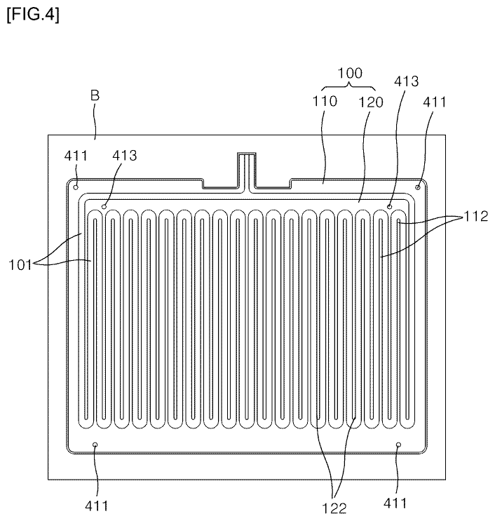

FIG. 4 shows an example in which a first flow path plate and a second flow path plate are piercing processed on a base plate according to the first embodiment of the present invention.

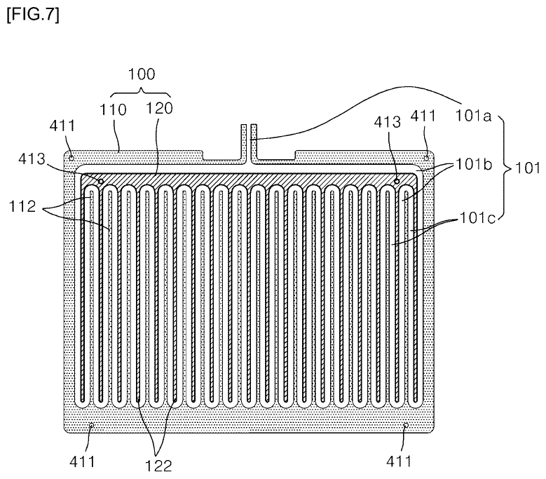

Referring to FIGS. 4 and 7, the separable flow path plates 100 includes a first flow path plate 110 and a second flow path plate 120.

The first flow path plate 110 and the second flow path plate 120 are formed by press processing one base plate B twice.

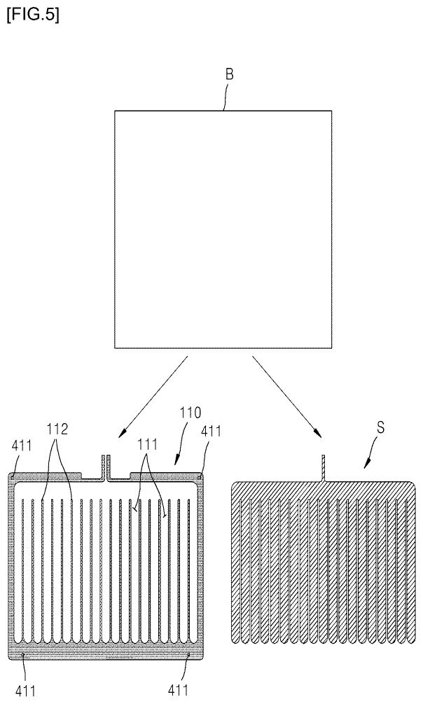

FIG. 5 shows an example in which a base plate according to the first embodiment of the present invention is piercing processed so that a first flow path plate and a scrab plate are formed.

Referring to FIG. 5, the first hole 111 and the first flow path guide 112 are formed in the first flow path plate 110.

The first flow path plate 110 is formed by shape-processing the base plate B in the outline shape of the pulsating heat pipe module.

The first hole 111 is a hole formed by piercing processing the base plate B in a preset first pattern.

The first pattern is pre-set according to the shape of the working fluid channel of the pulsating heat pipe module. In the present embodiment, it will be described that the working fluid channel is a zigzag-shaped flow path, and thus, the first pattern is designed in advance in a pattern that forms a part of the zigzag-shaped flow path. The width of the first hole 111 is formed greater than the width of the working fluid channel.

The first flow path guide 112 is formed in the shape of a rod that is elongated in one direction from the remaining part after the first hole 111 is piercing processed in the first flow path plate 110, and a plurality of first flow path guides 112 are spaced apart from each other by a predetermined distance. In the present embodiment, it will be described that the first flow path guide 112 is formed in a comb tooth shape of a comb.

The first flow path guides 112 are each formed long in the flow direction of the working fluid in the first flow path plate 110 and guide flow. The shape or size of the first flow path guides 112 is preset depending on the first pattern.

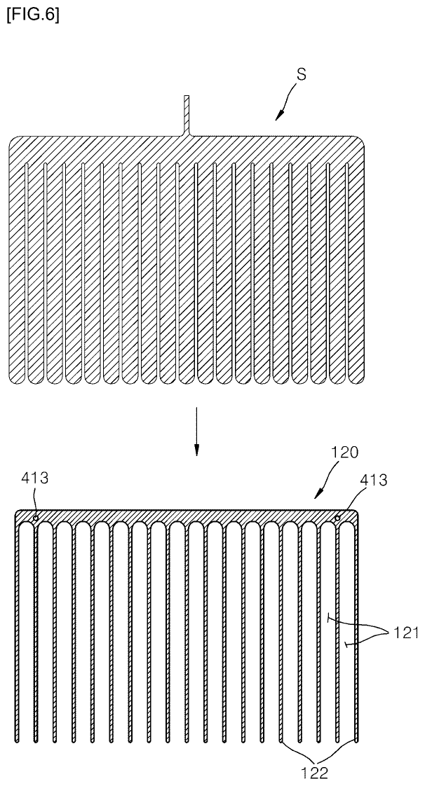

FIG. 6 shows an example in which the scrab plate according to the first embodiment of the present invention is piercing processed so that the second flow path plate is formed.

Referring to FIG. 6, the second hole 121 and the second flow path guide 122 are formed in the second flow path plate 120.

The second flow path plate 120 is formed by press processing the scrab plate S separated from the base plate B when the first flow path plate 110 is formed on the base plate B and recovered, and by piercing processing the second hole 121 in a preset second pattern.

That is, the second flow path plate 120 is a plate formed by press processing the scrab plate S that is the remaining part except for the first flow path plate 110 from the base plate B, once more. Thus, in the present invention, the waste portion from the base plate B may be minimized.

The second pattern is pre-set according to the shape of the working fluid channel of the pulsating heat pipe module. In the present embodiment, it will be described that the working fluid channel is a zigzag-shaped flow path, and thus, the second pattern is designed in advance in a pattern that forms a part of the zigzag-shaped flow path. The width of the second hole 121 is formed greater than the width of the working fluid channel.

The second flow path guide 122 is formed in the shape of a rod that is elongated in one direction from the remaining part after the second hole 121 is piercing processed in the second flow path plate 120, and a plurality of second flow path guides 122 are spaced apart from each other by a predetermined distance.

In the present embodiment, it will be described that the second flow path guide 122 is formed in a comb tooth shape of a comb. That is, the first flow path guide 112 and the second flow path guide 122 are formed in the comb tooth shape in opposite directions and are arranged to cross each other, thereby forming the working fluid channel 101.

The second flow path guides 122 are each formed long in the flow direction of the working fluid in the second flow path plate 120 and guide flow. The shape or size of the second flow path guides 122 is preset depending on the second pattern.

FIG. 7 shows separable flow path plates on which a second flow path plate is arranged in a first hole of a first flow path plate according to the first embodiment of the present invention.

Referring to FIG. 7, when the second flow path plate 120 is arranged in the first hole 111 of the first flow path plate 110, a flow path between the first flow path plate 110 and the second flow path plate 120 forms the working fluid channel 101 on which the working fluid flows when the pulsating heat pipe module is operated.

The working fluid channel 101 is a closed-loop flow path formed by the first flow path guide 112 and the second flow path guide 122. The first flow path guide 112 and the second flow path guide 122 are alternately arranged to cross each other.

The width, length and shape, etc. of the working fluid channel 101 is designed in advance depending on characteristics of the working fluid.

In the present embodiment, it will be described that the working fluid channel 101 has at least a part that is a flow path in a zigzag shape.

The working fluid channel 101 includes a working fluid injection hole 101a, a plurality of first flow path holes 101b, and a plurality of second flow path holes 101c.

The working fluid injection hole 101a is formed in the first flow path plate 110 and a working fluid injection flow path used when the working fluid is injected into the pulsating heat pipe module. The width, length or shape of the working fluid injection hole 101a may be variously changed. An inlet port of the working fluid injection hole 101a is sealed after the working fluid is injected.

The first flow path holes 101b communicate with the working fluid injection hole 101a, are formed long in one direction (−Y), are spaced apart from each other by a set distance and are formed to guide the working fluid in the one direction (−Y). However, embodiments are not limited thereto, and the width, length or shape of the first flow path holes 101b may be variously changed.

The first flow path holes 101b and the second flow path holes 101c are alternately arranged.

It will be described that the second flow path holes 101c are formed in the same shape as the first flow path holes 101b. A plurality of second flow path holes 101c are each formed long in the one direction (−Y) and are formed to guide the working fluid in an opposite direction (Y) to the one direction. However, embodiments are not limited thereto, and the width, length or shape of the second flow path holes 101c may be variously changed.

Meanwhile, the upper plate 200 is a flat plate shape-processed in a shape corresponding to the outline shape of the first flow path plate 110 to be stacked on the upper surface of the separable flow path plates 100. That is, a flow path is not formed on the upper plate 200, and the upper plate 200 is formed to cover the open upper surface of the working fluid channel 101 formed on the separable flow path plates 100.

The lower plate 300 is a flat plate shape-processed in a shape corresponding to the outline shape of the first flow path plate 110 to be stacked on the lower surface of the separable flow path plates 100. That is, a flow path is not formed on the lower plate 300, and the lower plate 300 is formed to cover the open lower surface of the working fluid channel 101 formed on the separable flow path plates 100.

The upper plate 200 and the lower plate 300 are formed with the same thickness and the same shape and are manufactured in the same process and in the same manner and thus the upper plate 200 and the lower plate 300 are compatible with each other. However, embodiments are not limited thereto, and the upper plate 200 and the lower plate 300 may have the same shape but may have different thicknesses.

Meanwhile, the first flow path plate 110, the second flow path plate 120, the upper plate 200, and the lower plate 300 include an assembly guide portion for guiding mutual coupling positions.

The assembly guide portion includes a first protrusion 401, a second protrusion 402, a first coupling hole 411, a second coupling hole 412, a third coupling hole 413, and a fourth coupling hole 414.

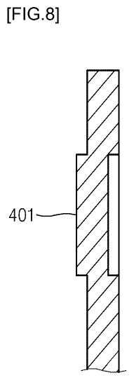

Referring to FIG. 8, the first protrusion 401 is press-formed using a forming press mold to be protrude from at least one of the upper plate 200 and the lower plate 300 in a direction toward the other one. In the present embodiment, it will be described that the first protrusion 401 protrudes from the lower plate 300 in a direction toward the upper plate 200.

It will be described that a total of four first protrusions 401 are formed at upper left, right edges and lower left and right edges on the front surface of the lower plate 300. However, embodiments are not limited thereto, and when the first protrusion 401 may guide an assembly position with the first flow path plate 110, the number, shape, and position of the first protrusions 401 may be variously changed and applicable.

The second protrusion 402 is press-formed using a forming press mold to be protrude from at least one of the upper plate 200 and the lower plate 300 in a direction toward the other one. In the present embodiment, it will be described that the second protrusion 402 also protrudes from the lower plate 300 in a direction toward the upper plate 200. However, embodiments are not limited thereto, and the first protrusion 401 and the second protrusion 402 may be all formed on the upper plate 200 and may also be formed on each of the upper plate 200 and the lower plate 300.

A total of two second protrusions 402 are formed at upper left and right edges on the front surface of the lower plate 300. That is, since the second protrusion 402 needs to be coupled to the third coupling hole 413 of the second flow path plate 120, the second protrusions 402 are formed at a position where the second protrusion 402 is spaced apart from the first protrusion 401 in an inward direction, and two second protrusions 402 are formed. It will be described that the size and shape of the second protrusion 402 are the same as in the first protrusion 401. However, embodiments are not limited thereto, and when the second protrusion 402 may guide the assembly position with the second flow path plate 120, the number, shape, and position of the second protrusions 402 may be variously changed and applicable.

The first coupling hole 411 is a hole that is formed in the first flow path plate 110 and is piercing processed through which the first protrusion 401 of the lower plate 300 passes.

It will be described that the first coupling hole 411 is formed at a position corresponding to the first protrusion 401 and a total of four first coupling holes 411 are formed in upper left and right edges and lower left and right edges of the first flow path plate 110.

The second coupling hole 412 is a hole that is formed in the upper plate 200 and is piercing processed so that the first protrusion 401 passing through the first coupling hole 411 is coupled.

It will be described that the second coupling hole 412 is formed at a position corresponding to the first protrusion 401 and a total of four second coupling holes 412 are formed in upper left and right edges and lower left and right edges of the upper plate 200.

The third coupling hole 413 is a hole that is formed in the second flow path plate 120 and is piercing processed through which the second protrusion 402 of the lower plate 300 passes.

It will be described that the third coupling hole 413 is formed at a position corresponding to the second protrusion 402 and a total of two third coupling holes 413 are formed in upper left and right edges and lower left and right edges of the second flow path plate 120.

The fourth coupling hole 414 is a hole that is formed in the upper plate 200 and is piercing processed so that the second protrusion 402 passing through the third coupling hole 413 is coupled.

It will be described that the four coupling hole 414 is formed at a position corresponding to the second protrusion 402 and a total of two fourth coupling holes 414 are formed on the inner side of the second coupling hole 412 at upper left and right edges and lower left and right edges of the upper plate 200.

A method of manufacturing the pulsating heat pipe module according to the embodiment of the present invention having the above configuration will be described as below.

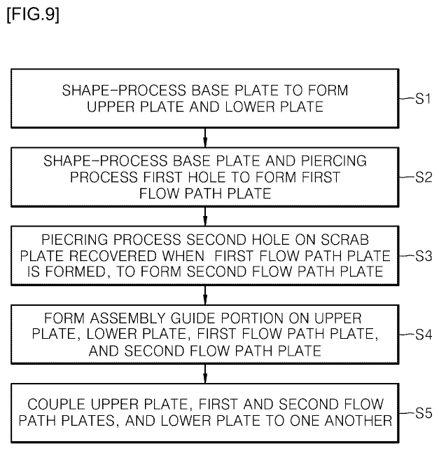

FIG. 9 is a flowchart illustrating a method of manufacturing a pulsating heat pipe module comprising separable flow path plates according to the first embodiment of the present invention.

Referring to FIG. 9, one base plate B among a plurality of base plates B having a preset thickness is shape-processed into a preset outline shape of the pulsating heat pipe module, thereby press-forming a cover plate used as the upper plate 200 and the lower plate 300 (S1).

The upper plate 200 and the lower plate 300 are formed using a pre-manufactured first press mold (not shown) so as to shape-process the outline shape of the pulsating heat pipe module.

When the shape-processing of the upper plate 200 and the lower plate 300 is performed, the first protrusion 401 and the second protrusion 402 are formed in at least one of the upper plate 200 and the lower plate 300, and the second coupling hole 412 and the fourth coupling hole 414 are piercing processed in the other one. In the present embodiment, it will be described that the second coupling hole 412 and the fourth coupling hole 414 are piercing processed in the upper plate 200 and the first protrusion 401 and the second protrusion 402 are formed in the lower plate 300, but embodiments are not limited thereto, and it is also possible to use the upper plate 200 and the lower plate 300 interchangeably.

Next, a first press-forming operation of forming the first flow path plate 110 using another base plate B among the plurality of base plates B is performed (S2).

In the first press-forming operation (S2), the base plate B is shape-processed into the outline shape of the pulsating heat pipe module, and the first hole 111 is piercing processed in a preset first pattern, so that the first flow path plate 110 having the plurality of flow path guides 112 in a comb tooth shape formed in the remaining part after the first hole 111 is piercing processed, may be formed.

Because the first hole 111 constitutes a part of the working fluid channel 101, the first pattern is designed in advance depending on the working fluid channel 101, and the working fluid channel 101 may be variously changed depending on characteristics of the working fluid and applicable. In the present invention, it will be described that the working fluid channel 101 is formed with a flow path in a zigzag shape, and thus, it will be described that the first hole 111 is one hole and has a comb tooth shape.

Referring to FIG. 5, in the first press-forming operation (S2), when the first flow path plate 110 is piercing processed in the base plate B, the scrab plate S that is the remaining part after the first flow path plate 110 is piercing processed, is separated.

It will be described that the first flow path plate 110 uses a second press mold (not shown) pre-manufactured so that the outline shape and the first hole 111 can be processed at one time.

However, embodiments are not limited thereto, and after the shape-processing of the first flow path plate 110 is performed using the first press mold (not shown), the first hole 111 may also be piercing processed through a separately-manufactured press mold. That is, after a plurality of plates are first press-formed in advance into the outline shape of the pulsating heat pipe module using the first press mold (not shown), some of the plurality of plates may also be used as the upper plate 200, and the other part may also be used as the lower plate 300, and another remainder may also be used as the first flow path plate 110.

Next, a second press-forming operation of forming the second flow path plate 120 is performed using the scrab plate S (S3).

Referring to FIG. 6, the second hole 121 is piercing processed in a second pattern preset in the scrab plate S, thereby forming the second flow path plate 120 having the plurality of flow path guides 122 in a comb tooth shape formed in the remaining part after the second hole 121 is piercing processed.

Because the second hole 121 constitutes a part of the working fluid channel 101, the second pattern is designed in advance depending on the working fluid channel 101. In the present embodiment, it will be described that the working fluid channel 101 is formed with a zigzag-shaped flow path, and thus the second hole 121 is set in a shape that crosses the first hole 111, and the second pattern is designed in advance so that the first hole 111 and the second hole 121 may form a zigzag-shaped flow path.

Because the second flow path plate 120 uses the remaining part after the first flow path plate 110 is piercing processed, material costs can be reduced.

Next, a third press-forming operation in which an assembly guide portion is formed in each of the first flow path plate 110, the second flow path plate 120, the upper plate 200 and the lower plate 300, is performed (S4).

The assembly guide portion includes the first and second protrusions 401 and 402 formed on the lower plate 300, the first coupling hole 411 formed in the first flow path plate 110, the third coupling hole 413 formed in the second flow path plate 120, and the second coupling hole 412 and the fourth coupling hole 414 formed in the upper plate 200.

The first protrusion 401 and the second protrusion 402 may be forming processed using a separately-manufactured forming press mold (not shown).

Referring to FIGS. 2 and 8, the first protrusion 401 is formed to protrude in a direction toward the first flow path plate 110 by pressing the rear surface of the lower plate 300.

The second protrusion 402 is also formed to protrude in the direction toward the first flow path plate 110 by pressing the rear surface of the lower plate 300.

In the present embodiment, it will be described that the first protrusion 401 and the second protrusion 402 are all formed on the lower plate 300. Since the first protrusion 401 needs to be coupled to the first flow path plate 110 and the second protrusion 402 needs to be coupled to the second flow path plate 110, positions of the first protrusion 401 and the second protrusion 402 are different from each other and a shape and a manufacturing method thereof are the same. The number, position and shape of the first and second protrusions 401 and 402 may be variously changed and applicable.

The first coupling hole 411 is piercing processed in the first flow path plate 110 so that the first protrusion 401 may pass through the first coupling hole 411.

The third coupling hole 413 is piercing processed in the second flow path plate 120 so that the second protrusion 402 may pass through the third coupling hole 413.

The second coupling hole 412 is piercing processed in the upper plate 200 so that the first protrusion 401 passing through the first coupling hole 411 of the first flow path plate 110 may be coupled.

In addition, the fourth coupling hole 414 is piercing processed in the upper plate 200 so that the second protrusion 402 passing through the third coupling hole 413 of the second flow path plate 120 may be coupled.

As described above, the first and second flow path plates 110 and 120 are formed through three times; first, second and third press-forming operations using one base plate B.

When the first and second flow path plates 110 and 120, the upper plate 200 and the lower plate 300 are manufactured, a cleaning process of removing foreign substances such as a press oil etc. that remains on surfaces thereof may be performed.

Next, the first and second flow path plates 110 and 120, the upper plate 200, and the lower plate 300 are mutually coupled to each other so that a coupling operation of completing the pulsating heat pipe module is performed (S5).

In the coupling operation, first, when the first coupling hole 411 of the first flow path plate 110 is engaged with the first protrusion 401 of the lower plate 300 at an upper side of the lower plate 300, the lower plate 300 and the first flow path plate 110 are coupled to each other.

The second flow path plate 120 is arranged inside the first hole 111 of the first flow path plate 110 at the upper side of the first flow path plate 110 coupled to the lower plate 300.

In this case, when the third coupling hole 413 of the second flow path plate 120 is engaged with the second protrusion 402 of the lower plate 300, the second flow path plate 120 is coupled to the lower plate 300.

By fitting the third coupling hole 413 into the second protrusion 402 and coupling the third coupling hole 413 to the second protrusion 402, the second flow path plate 120 may be automatically arranged at a preset assembly position inside the first hole 111 of the first flow path plate 110.

When the second flow path plate 120 is arranged inside the first hole 111 of the first flow path plate 110, the first flow path guides 112 and the second flow path guides 122 are alternately arranged so that a flow path between the first flow path guide 112 and the second flow path guide 122 forms the working fluid channel 101.

Thus, since the assembly position of the first flow path plate 110 and the second flow path plate 120 is aligned by fitting the third coupling hole 413 into the second protrusion 402 and coupling the third coupling hole 413 to the second protrusion 402, coupling of two first and second flow path plates 110 and 120 is very easy.

After the second flow path plate 120 is coupled, the upper plate 200 is stacked at the upper side of the second flow path plate 120.

In this case, when the second coupling hole 412 of the upper plate 200 is engaged with the first protrusion 401 passing through the first flow path plate 110 and the fourth coupling hole 414 of the upper plate 200 is engaged with the second protrusion 402 passing through the second flow path plate 120, the upper plate 200, the first and second flow path plates 110 and 120, and the lower plate 300 are coupled to one another.

That is, the first protrusion 401 of the lower plate 300 is engaged with and coupled to the first flow path plate 110 and the upper plate 200, and the second protrusion 402 of the lower plate 300 is engaged with and coupled to the second flow path plate 120 and the upper plate 200.

Thus, it is very easy to align a coupling position of a total of four, the upper plate 200, the first and second flow path plates 110 and 120 and the lower plate 200.

Subsequently, the upper plate 200, the first and second flow path plates 110 and 120, and the lower plate 300 may be coupled to one another by brazing. However, embodiments are not limited thereto, and various methods such as bonding except for brazing may be used.

As described above, in the present embodiment, two first and second flow path plates 110 and 120 are press-formed using one base plate, and a working fluid channel is formed using the first and second flow path plates 110 and 120 so that work is facilitated and time and costs can be reduced compared to an existing channel forming method such as etching and thus, productivity can be enhanced. In addition, since chemical solutions used in etching are not used, environmental hazards can be prevented.

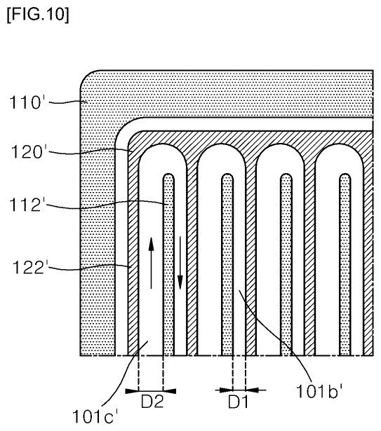

Meanwhile, FIG. 10 is a view illustrating flow path holes of a separable flow path plate according to a second embodiment of the present invention.

Referring to FIG. 10, the separable flow path plate according to the second embodiment of the present invention is different from the first embodiment in that the separable flow path plate according to the second embodiment of the present invention includes a first flow path plate 110′ and a second flow path plate 120′, and a flow path between a first flow path guide 112′ of the first flow path plate 110′ and a second flow path guide 122′ of the second flow path plate 120′ forms working fluid channels and a cross-sectional area D1 of first flow path holes 101b′ guiding a working fluid among the working fluid channels in one direction and a cross-sectional area D2 of second flow path holes 101c′ guiding the working fluid in an opposite direction to the one direction are formed differently, and the other configurations and operations are similar and thus detailed descriptions of similar configurations will be omitted,

The flow direction of the working fluid in the first flow path hole 101b′ and the second flow path hole 101c′ is opposite to each other, and the cross-sectional area D2 of the second flow path hole 101c′ where the working fluid moves upward, is formed greater than the cross-sectional area D1 of the first flow path hole 101b′ where the working fluid moves downward. That is, it will be described that the cross-sectional area D2 of the second flow path hole 101c′ is formed greater than the cross-sectional area D1 of the first flow path hole 101b′. The cross-sectional area D1 of the first flow path hole 101 b′ may be set in the range of 50% to 80% of the cross-sectional area D2 of the second flow path hole 101c′.

While the present invention has been particularly shown and described with reference to exemplary embodiments thereof, it will be understood by those of ordinary skill in the art that various changes in form and details may be made therein without departing from the spirit and scope of the present invention as defined by the following claims.

### Industrial Applicability

According to the present invention, a pulsating heat pipe module in which manufacturing is facilitated and manufacturing time and costs can be reduced, can be manufactured.

1. A method of manufacturing a pulsating heat pipe module comprising separable flow path plates, the method comprising:
a first press-forming operation in which a first flow path plate is formed by piercing processing a first hole in a preset first pattern on a first base plate;
a second press-forming operation in which a second flow path plate is formed by piercing processing a second hole in a preset second pattern on a scrab plate that is separated from the first base plate when the first flow path plate is formed and recovered; and
a coupling operation in which the second flow path plate is arranged inside the first hole of the first flow path plate so that a flow path between the first flow path plate and the second flow path plate constitutes a working fluid channel of a pulsating heat pipe module and an upper plate and a lower plate are stacked on upper and lower surfaces of the first and second flow path plates and coupled to each other, thereby completing the pulsating heat pipe module.

2. The method of claim 1, further comprising a third press-forming operation in which an assembly guide portion guiding a mutual coupling position on the first flow path plate, the second flow path plate, the upper plate, and the lower plate.

3. The method of claim 2, wherein the assembly guide portion comprises a first protrusion that is press-formed to protrude from at least one of the upper plate and the lower plate toward the other one, a first coupling hole formed in the first flow path plate and piercing processed so that the first protrusion passes through the first coupling hole, and a second coupling hole formed in the other one of the upper plate and the lower plate and piercing processed so that the first protrusion passing through the first coupling hole is coupled to the second coupling hole.

4. The method of claim 2, wherein the assembly guide portion comprises a second protrusion that is press-formed to protrude from at least one of the upper plate and the lower plate toward the other one, a third coupling hole formed in the second flow path plate and piercing processed so that the second protrusion passes through the third coupling hole, and a fourth coupling hole formed in the other one of the upper plate and the lower plate and piercing processed so that the second protrusion passing through the third coupling hole is coupled to the fourth coupling hole.

5. The method of claim 1, wherein a plurality of first flow path guides are formed in a shape of a rod that is elongated in one direction from a remaining part after the first hole is piercing processed in the first flow path plate.

6. The method of claim 5, wherein a plurality of second flow path guides are formed in a shape of a rod that is elongated in one direction from a remaining part after the second hole is piercing processed in the second flow path plate.

7. The method of claim 6, wherein, in the coupling operation, the first flow channel guides and the second flow path guides are alternately arranged to be spaced apart from one another by a preset distance.

8. The method of claim 1, wherein the first press-forming operation further comprises shape-processing a border of the first base plate in an outline shape of the pulsating heat pipe module.

9. The method of claim 1, wherein the upper plate and the lower plate are formed by shape-processing a second base plate in an outline shape of the pulsating heat pipe module.

10. The method of claim 1, wherein the working fluid channel has at least a part that is a flow path in a zigzag form, and the working fluid channel comprises a working fluid injection hole formed in the first flow path plate to inject a working fluid, first flow path holes that are connected to the working fluid injection hole, are formed long in one direction and are spaced apart from each other by a set distance to guide the working fluid in the one direction, and second flow path holes that are arranged alternately with the first flow path holes between the first flow path holes, are formed long in the one direction, and guide the working fluid passing through the first flow path holes in an opposite direction to the one direction.

11. The method of claim 10, wherein the first flow path holes and the second flow path holes have different cross-sectional areas.

12. A method of manufacturing a pulsating heat pipe module comprising separable flow path plates, the method comprising:
forming a cover plate used as an upper plate and a lower plate, by shape-processing two base plates among a plurality of base plates in a preset outline shape of a pulsating heat pipe module;
forming a first flow path plate in which the other base plate among the plurality of base plates is shape-processed in the outline shape and a first hole is piercing processed in a preset first pattern so that a plurality of rod-shaped first flow path guides are formed in a remaining part after piercing processing the first hole;
forming a second flow path plate in which a second hole is piercing processed in a preset second pattern to cross the first hole on a scrab plate that is separated from the base plate when the first flow path plate is formed and recovered, so that a plurality of rod-shaped second flow path guides are formed in a remaining part after piercing processing the second hole;
processing an assembly guide portion guiding a mutual coupling position on the first flow path plate, the second flow path plate, the upper plate, and the lower plate; and
arranging the second flow path plate inside the first hole of the first flow path plate, wherein the first flow path guides and the second flow path guides are alternately arranged so that a flow path between the first flow path guide and the second flow path guide constitutes a working fluid channel of the pulsating heat pipe module and stacking the upper plate and the lower plate on upper and lower surfaces of the first and second flow path plates and coupling the upper plate and the lower plate to each other to complete the pulsating heat pipe module.

13. A pulsating heat pipe module comprising separable flow path plates, comprising:
a first flow path plate formed by shape-processing a base plate in an outline shape of a pulsating heat pipe module and by piercing processing a first hole in a preset first pattern;
a second flow path plate, which is formed by piercing processing a second hole in a preset second pattern on a scrab plate that is separated from the base plate when the first flow path plate is formed and recovered and is arranged inside the first hole so that a flow path between the second flow path plate and the first flow path plate constitutes a working fluid channel of the pulsating heat pipe module;
an upper plate stacked on an upper surface of the first and second flow path plates and then coupled and shielding an upper surface of the working fluid channel; and
a lower plate stacked on a lower surface of the first and second flow path plates and then coupled and shielding a lower surface of the working fluid channel.

14. The pulsating heat pipe module of claim 13, further comprising an assembly guide portion that is press-formed on at least one of the first flow path plate, the second flow path plate, the upper plate, and the lower plate and guides an assembly position with the other plate.

15. The pulsating heat pipe module of claim 14, wherein the assembly guide portion comprises a first protrusion that is press-formed to protrude from at least one of the upper plate and the lower plate toward the other one, a first coupling hole formed in the first flow path plate and piercing processed so that the first protrusion passes through the first coupling hole, a second coupling hole formed in the other one of the upper plate and the lower plate and piercing processed so that the first protrusion passing through the first coupling hole is coupled to the second coupling hole, a second protrusion that is press-formed to protrude from at least one of the upper plate and the lower plate toward the other one, a third coupling hole formed in the second flow path plate and piercing processed so that the second protrusion passes through the third coupling hole, and a fourth coupling hole formed in the other one of the upper plate and the lower plate and piercing processed so that the second protrusion passing through the third coupling hole is coupled to the fourth coupling hole.
